(19) United States
(12) Patent Application Publication
(10) Pub. No.: US 2005/0272220 A1
(43) Pub. Date: Dec. 8, 2005

(54) Ultraviolet curing process for spin-on dielectric materials used in pre-metal and/or shallow trench isolation applications

(76) Inventors: Carlo Waldfried, Falls Church, VA (US); Orlando Escorcia, Falls Church, VA (US)

Correspondence Address: CANTOR COLBURN, LLP, 55 GRIFFIN ROAD SOUTH, BLOOMFIELD, CT, 06002, US

(21) Appl. No.: 11/146,744

(22) Filed: Jun. 7, 2005

Related U.S. Application Data
(60) Provisional application No. 60/577,679, filed on Jun. 7, 2004.

(51) Int. Cl. H01L 21/20; H01L 21/76; H01L 21/31; H01L 21/469

(52) U.S. Cl. 438/400; 438/778

(57) ABSTRACT

A UV curing process for a dielectric material used in pre-metal and shallow trench isolation applications comprises coating a suitable dielectric material onto a substrate; and exposing the dielectric material to ultraviolet radiation in an amount effective to reduce an organic content and/or increase a density and./or increase a wet etch resistance of the dielectric material. Optionally, the UV cured dielectric material may be exposed to multiple ultraviolet radiation patterns.

### CROSS REFERENCE TO RELATED APPLICATIONS

This application relates to and claims priority to U.S. Provisional Application No. 60/577,679 filed on Jun. 7, 2004, incorporated herein by reference in its entirety.

### BACKGROUND

The present disclosure generally relates to dielectric films in semiconductor devices, and more particularly, to ultraviolet (UV) curing processes for spin-on low k dielectric films used in pre-metal and shallow trench isolation applications.

In the field of advanced semiconductor fabrication, the dimensions of the devices and spacings formed continue to be decreased so as to improve integrated circuit performance. Fabrication often requires the deposition of dielectric materials into features patterned into layers of material on silicon substrates. In most cases, it is important that the dielectric material completely fill such features without formation of any voids. Filling such narrow features, which is also referred to as gap filling, places stringent requirements on materials used, for example, the dielectric material used for pre-metal dielectric (PMD) or shallow trench isolation (STI) applications. The pre-metal dielectric layer on an integrated circuit isolates structures electrically from metal interconnect layers and isolates them electrically from contaminant mobile ions that degrade electrical performance. According to International Technology Roadmap for Semiconductors, 2003 Edition, the aspect ratio required to be filled by the pre-metal dielectric material may be as high as 16:1 for DRAM devices in the year 2005, which translates to depths greater than 300 nanometers (nm). After gap fill, the dielectric materials need to be able to withstand subsequent processing steps, such as high temperature annealing, etching, and cleaning steps.

The dielectric materials employed for PMD and STI applications are generally deposited by chemical vapor deposition or by spin-on processes. Each of these approaches has some limitations for filling very narrow gaps that will need to be overcome for successful integration. Spin-on glasses and spin-on polymers such as silicates, siloxanes, silazanes or silisequioxanes generally have good gap-fill properties. The films of these materials are typically formed by applying a coating solution containing the polymer followed by a thermal cure process. The thermal cure process is generally performed to complete the formation of chemical bonds, outgas residual components, and reduce the dielectric constant in the film. This curing process is commonly performed in a furnace using a batch mode or on a hotplate utilizing a single wafer mode. In either case, the conventional cure process undesirably subjects the wafer to an elevated temperature for an extended period of time (e.g., in excess of one hour to several hours and at a temperature in greater than about 300° C.). These temperatures can exceed the allowable thermals budgets manufacturers are required to meet. Moreover, the thermal cure process which may involve process temperatures exceeding 800° C., can cause shrinkage. High amounts of shrinkage can lead to unacceptable film cracking and/or formation of a porous material, particularly inside narrow gaps. Cracked or porous material may have an undesirably high wet etch rate in subsequent process steps.

Because of at least these problems noted in the prior art relating to spin-on pre-metal dielectrics, it would be desirable to implement an alternative low k pre-metal dielectric cure process that minimizes shrinkage and provides improved wet etching resistance. It is further desirable to have a spin-on pre-metal dielectric that possesses the properties desired for successful integration.

### BRIEF SUMMARY

Disclosed herein are processes for UV curing a spin-on pre-metal dielectric material coated onto a surface of a substrate. In one embodiment, a UV curing process for a dielectric material used in pre-metal and shallow trench isolation applications comprises coating a dielectric material onto a substrate; and exposing the dielectric material to ultraviolet radiation in an amount effective to reduce an organic content in the dielectric material.

In another embodiment, a UV curing process for a dielectric material used in pre-metal and shallow trench isolation applications comprises coating a dielectric material onto a substrate; and exposing the dielectric material to ultraviolet radiation in an amount effective to densify the dielectric material.

In still another embodiment, a UV curing process for a dielectric material used in pre-metal and shallow trench isolation applications, comprises coating a dielectric material onto a substrate; and exposing the dielectric material to ultraviolet radiation in an amount effective to increase a wet etch resistance of the dielectric material , wherein the wet etch resistance increases relative to a wet etching rate of the dielectric material prior to the exposure.

In yet another embodiment, a process for curing a spin on pre-metal dielectric material coated onto a surface of a substrate comprises coating a spin on pre-metal dielectric material onto a substrate; exposing the spin on pre-metal dielectric material to a first ultraviolet radiation pattern for a period of time and intensity effective to increase an elastic modulus property and/or a hardness property of the pre-metal dielectric material; and exposing the spin on pre-metal dielectric material to a second ultraviolet radiation pattern for a period of time and intensity effective to further increase the elastic modulus property and/or the hardness property of the pre-metal dielectric material, wherein the first and second ultraviolet radiation patterns are different.

The above described and other features are exemplified by the following figures and detailed description.

### BRIEF DESCRIPTION OF THE DRAWINGS

Referring now to the figures, which are exemplary embodiments and wherein like elements are numbered alike:

FIG. 1 graphically illustrates the broadband spectral output of a Type I electrodeless microwave driven bulbs from Axcelis Technologies, Inc., respectively, which is suitably used for UV curing the dielectric materials;

FIG. 2 graphically illustrates the broadband spectral output of a Type II electrodeless microwave driven bulbs, respectively, which is suitably used for UV curing the dielectric materials;

FIG. 3 graphically illustrates FTIR spectra for a pre-metal dielectric film that was uncured and UV cured in accordance with one embodiment;

FIGS. 4-5 are charts illustrating wet etch resistance in various dilute hydrofluoric acid solutions (DHF) or non-UV cured and UV cured spin low k dielectric materials compared to a TEOS dielectric deposited by chemical vapor deposition;

FIGS. 6-7 are charts illustrating wet etch resistance as a function of time in various dilute hydrofluoric acid solutions for non-UV cured and UV cured spin low k dielectric materials compared to a TEOS dielectric deposited by chemical vapor deposition;

FIG. 8 is a chart illustrating dielectric constant for spin on pre-metal low k dielectric materials before and after UV exposure, wherein the process chamber employed different inert gases; and

FIG. 9 is a chart illustrating breakdown voltages for spin on pre-metal low k dielectric materials before and after UV exposure, wherein the process chamber employed different inert gases.

### DETAILED DESCRIPTION

The present disclosure is directed to a UV curing process for spin-on pre-metal dielectric materials. As used herein, reference to the term “pre-metal” dielectric is intended to include shallow trench dielectric applications, since these dielectric materials are generally the same and optimized for gap filling. Applying the UV cure process described herein will have similar advantages for both PMD and STI applications. The UV curing process generally includes spin coating the pre-metal dielectric material onto a suitable substrate prior to depositing any metal layers in the integrated circuit and exposing the dielectric material to ultraviolet radiation having one or more wavelengths greater than 150 nanometers to less than 400 nanometers at a temperature less than about 450° C.

While not wanting to be bound by theory, it is believed that the UV cure process removes organic-like impurities or moieties that may have been formed in the spin-on pre-metal dielectric material. The term spin-on dielectric material, as used herein, includes, but is not intended to be limited to, silicates, hydrogen silsesquioxanes, organosilsesquioxanes, organosiloxanes, organhydridosiloxanes, silsesquioxane-silicate copolymers, silazane-based materials, polycarbosilanes, and acetoxysilanes. The UV curing process removes and/or chemically modifies a portion of the dielectric material. For example, depending on the particular spin-on pre-metal dielectric material, the amounts of Si—H, Si—CH₃, SixCyHz, among others, in the coated dielectric material are reduced, wherein x, y, z, are generally an integer from 0 to 12 with the proviso that x=1 amd y+z is equal to or greater than 1. As a result, the UV curing process advantageously increases the density of the dielectric material, and/or reduces the organic content, and/or increases the wet etch resistance of the dielectric material.

The monomers, monomer mixtures and polymers described herein for forming the spin-on pre-metal dielectric material can be and in many ways are designed to be solvated or dissolved in any suitable solvent, so long as the resulting solutions can be spin coated or otherwise mechanically layered on to a substrate, a wafer, or a layered material. Preferred solutions are designed and contemplated to be spin coated, rolled, dripped or sprayed onto a wafer, a substrate, or the layered material. Most preferred solutions are designed to be spin coated onto a wafer, a substrate or layered material. Typical solvents are those solvents that are readily available to those in the field of dielectric materials, layered components, or electronic components.

Typical solvents are also those solvents that are able to solvate the monomers, isomeric monomer mixtures and polymers. Contemplated solvents include any suitable pure or mixture of organic, organometallic or inorganic molecules that are volatilized at a desired temperature. The solvent may also comprise any suitable pure or mixture of polar and non- polar compounds. In preferred embodiments, the solvent comprises water, ethanol, propanol, acetone, toluene, ethers, cyclohexanone, butyrolactone, methylethylketone, methylisobutylketone, N-methylpyrrolidone, polyethyleneglycolmethylether, mesitylene, and anisole.

In one embodiment, the UV curing process comprises spin coating a suitable pre-metal dielectric material onto a substrate, and exposing the pre-metal dielectric material to an ultraviolet radiation pattern at a temperature less than about 450° C. for a period of time effective to increase the density and/or increase the wet etch resistance and/or decrease the organic content in the dielectric material. There are numerous methods of coating a spin-on dielectric material as is known in the art, and all of the known methods are considered appropriate. Suitable substrates contemplated herein may comprise any desirable substantially solid material for which a pre-metal dielectric or shallow trench isolation structure including the spin-on dielectric material may be desired. For example, suitable substrates include, but are not limited to, silicon, silicon dioxide, glass, silicon nitride, ceramics, and gallium arsenide. The term substrates also generally refers to any of the layers, planarized or having topography, including, semiconducting wafers, dielectric layers, gates, barrier layers, etch stop layers, and metal lines found in integrated circuit devices.

Optionally, an annealing process may be employed after the UV cure process. The annealing processes can comprise exposing the substrate containing the UV cured pre-metal dielectric material to an elevated temperature for a period of time effective to increase the density and/or increase the wet etch resistance and/or decrease the organic content in the dielectric material. For example, the annealing temperature may be up to about 1,100° C. for about 2 hours or less.

As previously described, the resulting UV cured pre-metal dielectric material has been found to be more stable to a subsequent wet chemical treatment processes, such as is commonly employed during the integrated circuit fabrication process. For example, after lithography, a wet etching process may be employed to selectively remove portions of the substrate and/or deposited layers. Typically, the substrate is immersed into a stripper such as a dilute aqueous hydrofluoric acid bath. Other wet strippers include acids, bases, and solvents as are known to those skilled in the art. The particular wet strippers used are well within the skill of those in the art. For example, nitric acid, sulfuric acid, ammonia, hydrofluoric acid are commonly employed as wet strippers. In operation, the wet stripper is immersed, puddled, streamed, sprayed, or the like onto the substrate and subsequently rinsed with deionized water. As will be discussed in greater detail below, the UV cured spin on dielectric material has improved wet etch resistance relative to the same material that was not exposed to the UV cure process.

In the UV curing process, a UV irradiator tool is utilized. A suitable UV irradiator tool is the RapidCure™ tool commercially available from Axcelis Technologies, Incorporated. During use, the light source chamber may be purged with an inert gas such as nitrogen, helium, or argon to allow the UV radiation to enter an adjacent process chamber with minimal spectral absorption. The pre-metal dielectric material is positioned within the process chamber, which is purged separately and process gases, such as N₂, H₂, Ar, He, Ne, H₂O vapor, CO_{z}, O_{z}, CₓH_{y}, CₓF_{y}, CₓH_{z}F_{y}, and mixtures thereof, wherein x is an integer between 1 and 6, y is an integer between 4 and 14, and z is an integer between 1 and 3, may be utilized for different applications. In this regard, UV curing can occur at vacuum conditions, or at conditions without the presence of oxygen, or with oxidizing gases. In one embodiment, the process chamber is purged with a hydrogen and helium gas.

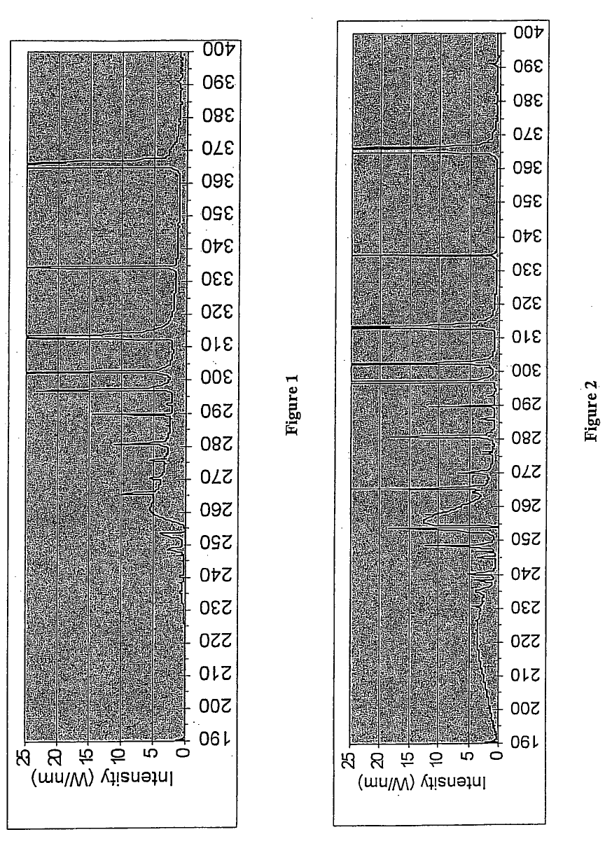

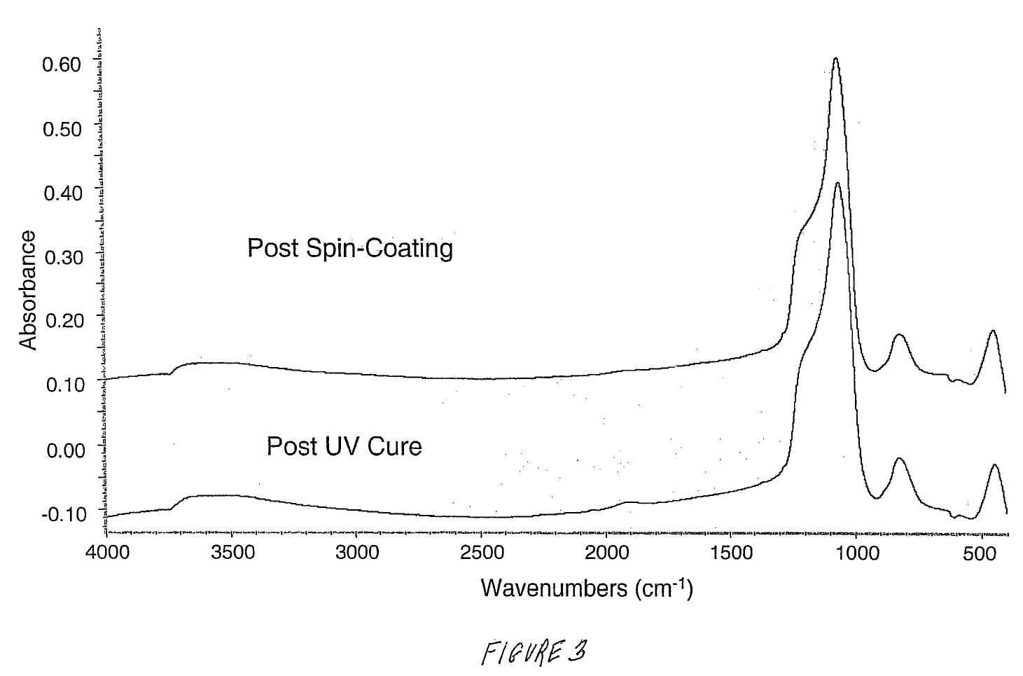

The UV light source can be microwave driven, arc discharge, dielectric barrier discharge, or electron impact generated. Moreover, UV generating bulbs with different spectral distributions may be selected depending on the application such as, for example, microwave electrodeless bulbs identified as Type I or Type II and available from Axcelis Technologies (Beverly, Mass.). Spectra obtained from the Type I and Type II bulbs and suitable for use in the UV cure process are shown in FIGS. 1 and 2, respectively.

The substrate (wafer) temperature may be controlled ranging from room temperature to 450° C., optionally by an infrared light source, an optical light source, a hot surface, or the light source itself. The process pressure can be less than, greater than, or equal to atmospheric pressure. Typically, the UV cured dielectric material is UV treated for no more than or about 600 seconds, and preferably no more than about 300 seconds and, more particularly, between about 60 and about 180 seconds. Also, UV treating the dielectric material can be performed at a temperature between about room temperature and about 450° C.; at a process pressure that is less than, greater than, or about equal to atmospheric pressure; at a UV power between about 0.1 and about 2,000 mW/cm²; and a UV wavelength spectrum between about 100 and about 400nm.

The disclosure is further illustrated by the following non-limiting examples.

### EXAMPLE 1

### Wet Etch Resistance of Pre-Metal Dielectric Material

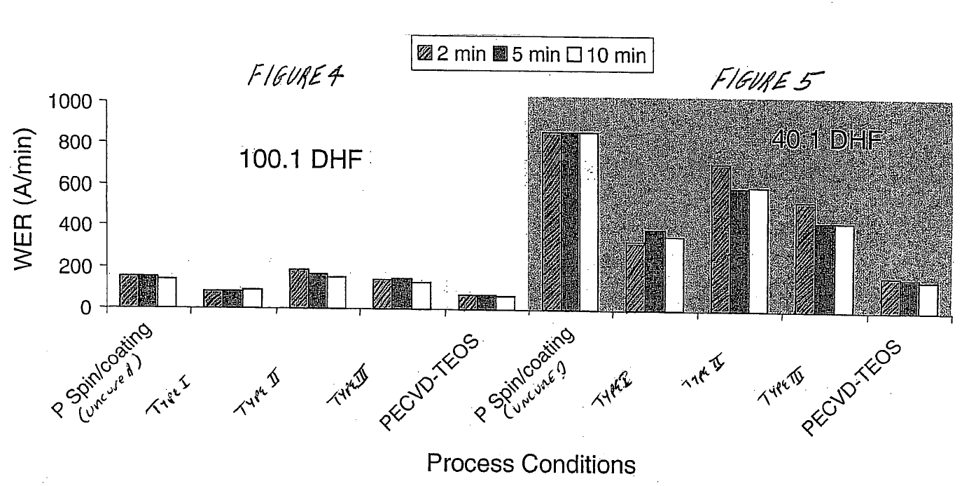

In this Example, a pre-metal dielectric material identified as Honeywell Electronic Material A (HEMA) and obtained from Honeywell Company was spin coated onto bare silicon wafers. The wafers were subjected to a conventional spin process recommended by the manufacturer. Each wafer was processed identically. The coated wafers were exposed to a UV cure process at 425° C. for a period of 5 minutes. The UV cure process employed various microwave electrodeless bulbs in a Rapid Cure Exposure tool commercially available from Axcelis Technologies, Incorporated. FTIR data as shown in FIG. 3 did not show any detectable absorbance changes in the low k dielectric material after the UV cure. The UV cured wafers were then exposed to a wet etching process that comprised immersing the wafers in a 40:1 and a 100:1 dilute hydrofluoric acid aqueous based solution for 2 minutes, 5 minutes, and 10 minutes. The above ratio represents the amount by weight of water to hydrofluoric acid. The results are shown in FIGS. 4, 5 and are shown relative to a tetraorthosilicate (TEOS) films deposited using plasma enhanced chemical vapor deposition (PECVD), which is generally known for its wet etch resistance but is unsuitable for use as a pre-metal dielectric material for advanced design rules, e.g., less than 90 nanometers.

As shown, the UV cure process clearly reduced the pre-metal dielectric wet etch resistance in the 40:1 hydrofluoric acid solution. The etching rate was about 820 angstroms/minute for the uncured material, which was reduced to as much as about 350 angstroms/minute depending on the composition of the pre-metal dielectric material. The time variable had minimal effect. Comparable results were observed in the more dilute HF solution (100:1). However, the results were less visibly dramatic due to the relatively weak etching behavior observed as a result of the dilution.

### EXAMPLE 2

### Wet Etch Resistance of HEMA Based Spin-on Dielectric Material

In this example, the HEMA pre-metal spin-on dielectric material was spin coated onto blank wafers as in Example 1. In addition, a nanoglass spin on dielectric material available from the Honeywell Corporation under the identifier NGX was spin coated onto blank wafers. The wafers were exposed to UV radiation produced in the RapidCure tool utilizing a Type III electrodeless bulb at 425° C. for 10 minutes in an inert gas mixture. The thickness and the refractive index (RI) after the spin on dielectric was post baked and after the UV cure process were measured. Some of the wafers were further exposed to a furnace anneal process at 900° C. or 1000° C. for 1 hour. Percent shrinkage is calculated based on the thickness before and after UV cure process, and anneal, if applicable. In this Example, wafer set number 1 refers to the HEMA spin coated dielectric materials, and wafer set numbers 2 and 3 refer to the spin coated NGX low k dielectric materials, wherein each wafer set represents the average of three processed wafers. The data is presented in Table 1.

TABLE 1

| | | Post Bake | | Post Cure | | | Post Anneal | | |
|---|---|---|---|---|---|---|---|---|---|
| | | [PB] | | [PC] | | | [PA] | | |
| Wafer | Furnace | Thickness | | Thickness | | Shrinkage | Thickness | | Shrinkage |
| Set No. | Anneal | (nm) | PB-RI | (nm) | PC-RI | (%) | (nm) | PA-RI | (%) |
| 1 | None | 5789 | 1.49 | 5756 | 1.5 | 0.57 | | | |
| 2 | 900° C. | 7804 | 1.41 | 7510 | 1.40 | 3.77 | 5826 | 1.50 | 22.42 |
| 3 | 1000° C. | 7788 | 1.41 | 7549 | 1.40 | 3.07 | 5623 | 1.50 | 25.51 |

The results show that the UV cure process exhibited minimal shrinkage and minimal change in refractive index. However, the post anneal process did cause film densification and/or loss as well as an increase in the refractive index. The relevant peaks associated with the dielectric material obtained from FTIR data is presented in Table 2. PB refers to the dielectric material after a spin coating and post bake process; PC refers to the PB dielectric after UV curing; and PA refers to the dielectric after PB and PC and exposure to a furnace anneal process.

TABLE 2

| | Furnace | | | | | | | | | | | | |
|---|---|---|---|---|---|---|---|---|---|---|---|---|---|
| Wafer from | Anneal | OH/SiO | | | SiC/SiO | | | CH/SiO | | | C + C/SiO | | |
| Set No. | (° C.) | PB | PC | PA | PB | PC | PA | PB | PC | PA | PB | PC | PA |
| 1 | None | 0.06 | 0.103 | 0 | 0 | 0 | | 0 | 0 | | 0.0156 | 0.0071 | |
| 2 | 900 | 0.026 | 0 | 0.0606 | 0.031 | 0.028 | 0 | 0.008 | 0.008 | 0 | 0 | 0 | 0.0159 |
| 3 | 1000 | 0.028 | 0 | 0.1131 | 0.031 | 0.029 | 0 | 0.008 | 0.009 | 0 | 0 | 0 | 0.0181 |

The FTIR data showed that the UV cure process leads to a decreased C═C peak and exhibited minimal effect on the Si-OH content of the pre-metal dielectric material.

### EXAMPLE 3

In this Example, the dielectric constant and breakdown voltage was measured before and after the UV cure process as in Example 1. Spin low k dielectrics identified as HEMA (m1), (m2), and (m3) were coated using a conventional spin coat process as recommended by the manufacturer for the particular low k dielectric. The results are shown in Table 3 below.

TABLE 3

| | HEMA (m1) | | HEMA (m2) | | HEMA (m3) | |
|---|---|---|---|---|---|---|
| | Pre | Post | Pre | Post | Pre | Post |
| | UV | UV | UV | UV | UV | UV |
| | Cure | Cure | Cure | Cure | Cure | Cure |
| Dielectric | 7.84 | 6.91 | 6.27 | 6.19 | 7.6 | 6.7 |
| Constant | | | | | | |
| Breakdown | 0.58 | 1.88 | 1.99 | 2.04 | 1.24 | 2.27 |
| Voltage | | | | | | |

In each instance, exposing the spin-on dielectric material to the UV cure process advantageously decreased the dielectric constant. Along with the decrease in dielectric constant a concomitant increase in breakdown voltage was observed.

### EXAMPLE 4

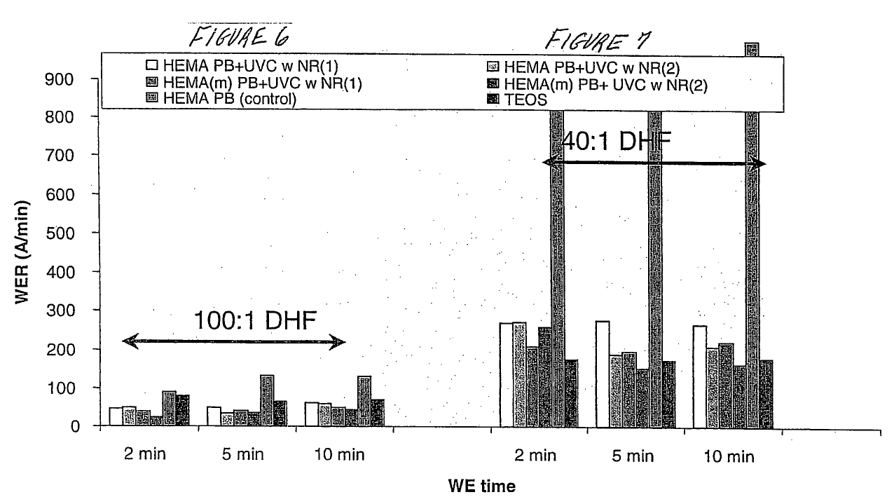

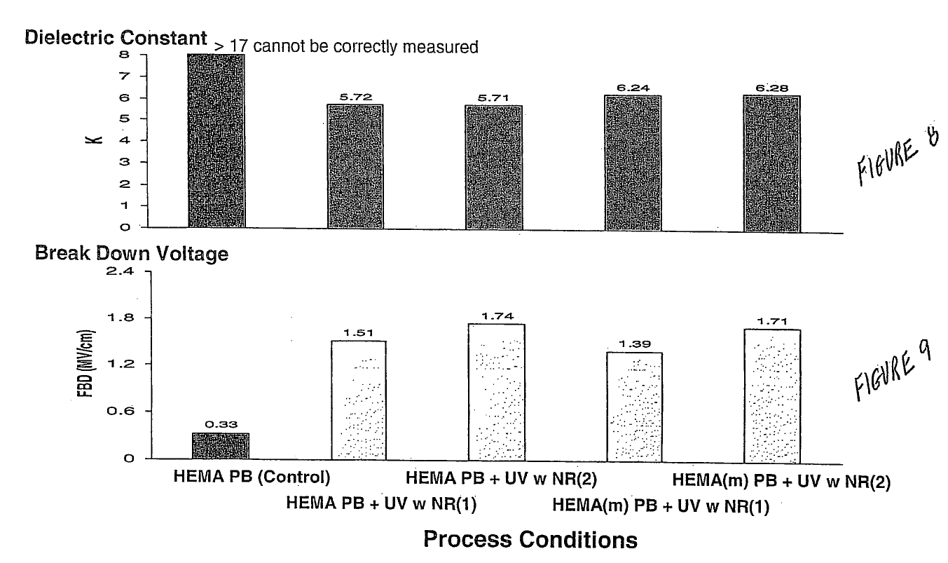

In this Example, the effect caused by the use of different purge gases in the process chamber was observed. The wafers were processed as in Example 1. NR(1) refers to the use of helium as the inert gas whereas NR(2) refers to the use of a hydrogen/helium gas mixture. As shown in FIGS. 6, 7, the UV cure process significantly improved wet etch resistance in dilute hydrofluoric acid solutions of 40:1 and 100:1. In some instances, wet etch resistance was superior to a TEOS PECVD deposited film. FIGS. 8 and 9 graphically illustrate dielectric constant and breakdown voltage for the respective films. The UV cure process significantly improves dielectric constant and breakdown voltage.

While the disclosure has been described with reference to an exemplary embodiment, it will be understood by those skilled in the art that various changes may be made and equivalents may be substituted for elements thereof without departing from the scope of the disclosure. In addition, many modifications may be made to adapt a particular situation or material to the teachings of the disclosure without departing from the essential scope thereof. Therefore, it is intended that the disclosure not be limited to the particular embodiment disclosed as the best mode contemplated for carrying out this disclosure, but that the disclosure will include all embodiments falling within the scope of the appended claims.

1. A UV curing process for a dielectric material used in pre-metal and shallow trench isolation applications, comprising:
coating a dielectric material onto a substrate; and
exposing the dielectric material to ultraviolet radiation in an amount effective to reduce an organic content in the dielectric material.

2. The process of claim 1, wherein exposing the dielectric material to the ultraviolet radiation comprises forming an atmosphere about the dielectric material, wherein the atmosphere comprises N₂, H₂, Ar, He, Ne, H₂O vapor, CO_{z}, O_{z}, CₓH_{y}, CₓF_{y}, CₓH_{z}F_{y}, and mixtures thereof, wherein x is an integer between 1 and 6, y is an integer between 4 and 14, and z is an integer between 1 and 3.

3. The process of claim 1, wherein the ultraviolet radiation pattern comprises wavelengths greater than 150 nanometers to less than 400 nanometers.

4. The process of claim 1, further comprising heating the substrate during the exposure.

5. The process of claim 1, wherein the pre-metal dielectric material comprises hydrogen silsesquioxanes, alkyl silsesquioxanes, carbon doped oxides, hydrogenated silicon oxy-carbides, B-staged polymers, arylcyclobutene-based polymers, polyphenylene-based polymers, polyarylene ethers, polyimides, porous silicas, and combinations comprising at least one of the foregoing dielectric materials.

6. The process of claim 1, wherein the spin on pre-metal dielectric material has substantially the same dielectric constant before and after exposure to the ultraviolet radiation.

7. The process of claim 1, wherein the elastic modulus property and/or the hardness property of the pre-metal dielectric material increases by at least about 50% during the exposure.

8. The process of claim 1, wherein exposing the spin on pre-metal dielectric material to the ultraviolet radiation pattern for a period of time and intensity is effective to decrease the dielectric constant.

9. The process of claim 1, further comprising exposing the spin on pre-metal dielectric material to a furnace cure process or a hot place cure process subsequent to exposing the spin on pre-metal dielectric material to the ultraviolet radiation pattern.

10. A UV curing process for a dielectric material used in pre-metal and shallow trench isolation applications, comprising:
coating a dielectric material onto a substrate; and
exposing the dielectric material to ultraviolet radiation in an amount effective to densify the dielectric material.

11. The process of claim 10, wherein exposing the dielectric material to the ultraviolet radiation comprises forming an atmosphere about the dielectric material, wherein the atmosphere comprises N₂, H₂, Ar, He, Ne, H₂O vapor, CO_{z}, O_{z}, CₓH_{y}, CₓF_{y}, CₓH_{z}F_{y}, and mixtures thereof, wherein x is an integer between 1 and 6, y is an integer between 4 and 14, and z is an integer between 1 and 3.

12. The process of claim 10, wherein the ultraviolet radiation pattern comprises wavelengths greater than 150 nanometers to less than 400 nanometers.

13. The process of claim 10, further comprising heating the substrate during the exposure.

14. The process of claim 10, wherein the pre-metal dielectric material comprises hydrogen silsesquioxanes, alkyl silsesquioxanes, carbon doped oxides, hydrogenated silicon oxy-carbides, B-staged polymers, arylcyclobutene-based polymers, polyphenylene-based polymers, polyarylene ethers, polyimides, porous silicas, and combinations comprising at least one of the foregoing dielectric materials.

15. The process of claim 10, wherein the spin on pre-metal dielectric material has substantially the same dielectric constant before and after exposure to the ultraviolet radiation.

16. The process of claim 10, wherein the elastic modulus property and/or the hardness property of the pre-metal dielectric material increases by at least about 50% during the exposure.

17. The process of claim 10, wherein exposing the spin on pre-metal dielectric material to the ultraviolet radiation pattern for a period of time and intensity is effective to decrease the dielectric constant.

18. The process of claim 10, further comprising exposing the spin on pre-metal dielectric material to a furnace cure process or a hot place cure process subsequent to exposing the spin on pre-metal dielectric material to the ultraviolet radiation pattern.

19. A UV curing process for a dielectric material used in pre-metal and shallow trench isolation applications, comprising:
coating a dielectric material onto a substrate; and
exposing the dielectric material to ultraviolet radiation in an amount effective to increase a wet etch resistance of the dielectric material , wherein the wet etch resistance increases relative to a wet etching rate of the dielectric material prior to the exposure.

20. A process for curing a spin on pre-metal dielectric material coated onto a surface of a substrate, comprising:
coating a spin on pre-metal dielectric material onto a substrate;
exposing the spin on pre-metal dielectric material to a first ultraviolet radiation pattern for a period of time and intensity effective to increase an elastic modulus property and/or a hardness property of the pre-metal dielectric material; and
exposing the spin on pre-metal dielectric material to a second ultraviolet radiation pattern for a period of time and intensity effective to further increase the elastic modulus property and/or the hardness property of the pre-metal dielectric material, wherein the first and second ultraviolet radiation patterns are different.

21. The process of claim 20, wherein the first and second ultraviolet radiation patterns comprise wavelengths greater than 150 nanometers to less than 400 nanometers.

22. The process of claim 20, further comprising heating the substrate during the exposure.

23. The process of claim 20, wherein the pre-metal dielectric material comprises hydrogen silsesquioxanes, alkyl silsesquioxanes, carbon doped oxides, hydrogenated silicon oxy-carbides, B-staged polymers, arylcyclobutene-based polymers, polyphenylene-based polymers, polyarylene ethers, polyimides, porous silicas, and combinations comprising at least one of the foregoing dielectric materials.

24. The process of claim 20, wherein coating the spin on pre-metal dielectric material onto the substrate is at an aspect ratio greater than 300 nanometers.
